(19) United States
(12) Patent Application Publication
(10) Pub. No.: US 2026/0128723 A1
(43) Pub. Date: May 7, 2026

(54) MULTILAYER PIEZOELECTRIC DEVICE WITH PIEZO-LAYER TRENCH WITH WIDER IDT EDGE REGION

(71) Applicant: Skyworks Solutions, Inc., Irvine, CA (US)

(72) Inventors: Rei Goto, Osaka-Shi (JP); Shoji Okamoto, Hirakata-Shi (JP)

(21) Appl. No.: 19/378,206

(22) Filed: Nov. 3, 2025

Related U.S. Application Data
(60) Provisional application No. 63/716,149, filed on Nov. 4, 2024.

(51) Int. Cl. H03H 9/13; H03H 9/15; H03H 9/54

(52) U.S. Cl. CPC H03H 9/133; H03H 9/15; H03H 9/54

(57) ABSTRACT

An acoustic wave device, a radio frequency filter, and an electronics module are provided. The acoustic wave device includes a layer of carrier substrate, a layer of dielectric material, a layer of piezoelectric material, a pair of interdigital transducer electrodes, each interdigital transducer electrode including a bus bar and a plurality of electrode fingers extending from the bus bar to the distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having a width at their distal end that is greater than the width of the rest of the electrode finger. The acoustic wave device provides effective suppression of transverse modes.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the disclosure relate to an acoustic wave device, a radio frequency filter including the same, and an electronics module comprising at least one radio frequency filter including the same. In particular, embodiments of the disclosure relate to an acoustic wave device including trench portions in a piezoelectric layer and electrode fingers having a width at their distal end that is greater than the width of the rest of the electrode finger for transverse mode suppression.

### Description of the Related Technology

Multilayer piezoelectric substrates (MPSs) are often used in acoustic wave devices, such as surface acoustic wave (SAW) devices. Several structures for suppressing unwanted transverse modes in such devices are known. However, the various known structures each have different drawbacks.

FIGS. 1A and 1B show one type of acoustic wave device 100. FIG. 1A is a cross section through the line marked A on the plan view of FIG. 1B. The acoustic wave device 100 has a multilayer piezoelectric substrate (MPS) including a carrier substrate 102, a layer of dielectric material 104 disposed on an upper surface of the carrier substrate 102, and a layer of piezoelectric material 106 disposed on the layer of dielectric material 104. An interdigital transducer (IDT) 108 is disposed on top of the layer of piezoelectric material 106. In the acoustic wave device 100 of FIGS. 1A and 1B, the electrode fingers in the IDT 108 include hammer head portions 110 to suppress the transverse modes. The hammer head portions 110 are sections of the electrode fingers in edge regions E of the IDT that have a width (in a direction perpendicular to the lengthwise extension of the electrode fingers) larger than the width of each finger in a central region C of the IDT 108. In other words, a duty factor (DF) of the IDT 108 is greater in the edge regions E of the IDT compared to the duty factor of the IDT in the central region C of the IDT.

An illustrative diagram showing what is meant by the term Duty Factor is provided in FIG. 4. In general, the width of the IDT fingers (w) compared to the width of the spacing between the same part of the IDT fingers (p) sets the duty factor (DF). Specifically, the duty factor is defined as the fraction of the IDT width spanned by the width of the IDT fingers (in the direction of propagation of the main surface acoustic wave to be generated). Increasing the width of the IDT fingers, whilst maintaining the position of the center of each IDT finger, increases the duty factor. The DF can be expressed as:

$$DF = \frac{w}{p}$$

The hammer head portions 110 of the device of FIGS. 1A and 1B reduce the acoustic velocity in the edge regions E compared to the central region C. This velocity reduction creates a piston mode distribution to reduce transverse modes. In order to obtain a large enough velocity difference for transverse mode suppression through a larger DF in the edge regions E, the DF of the central region C of the IDT needs to be less than 0.5. This is because the velocity of the main acoustic mode changes rapidly with DF when the DF is less than 0.5, compared to when DF is greater than 0.5 and the velocity of the main acoustic mode does not vary with DF as much. The requirement of a DF smaller than 0.5 in the central region C leads to a decrease in the static capacitance. A smaller static capacitance leads to a larger size device for a given impedance, as static capacitance sets the limit on the IDT size. Therefore, the hammer head structure of FIGS. 1A and 1B can lead to an undesirable increase in size of the acoustic wave device 100.

FIG. 2A is a plan view of a surface acoustic wave (SAW) device (e.g., a SAW resonator). As shown in FIGS. 2C and 2E, the SAW device includes a trench region 210. FIGS. 2B and 2C show cross sections through the lines in FIG. 2A labeled A and B respectively. FIGS. 2D and 2E show partial cross sections through the lines in FIG. 2A labeled X and Y respectively (with only two IDT fingers shown in FIGS. 2D and 2E for clarity).

The acoustic wave device 200 includes a carrier substrate 202, a layer of dielectric material 204 disposed on an upper surface of the carrier substrate 202, and a layer of piezoelectric material 206 disposed above the layer of dielectric material 204 on the upper surface of the carrier substrate 202. Together the carrier substrate 202, layer of dielectric material 204, and layer of piezoelectric material 206 may be referred to as a multilayer piezoelectric substrate (MPS). As can be seen in FIG. 2A, the IDT fingers of acoustic wave device 200 have a uniform width along their length. The acoustic wave device also includes electrodes 208a and 208b disposed above the layer of piezoelectric material 206.

The acoustic wave device 200 further includes trench structures in the layer of piezoelectric material for suppressing transverse modes. Trench portions 210 are located in the upper surface of the layer of piezoelectric material. The trench portions 210 overlap with the edge regions E of the IDT electrodes 208. In other words, the trench portions 210 are located within the active region of the IDT 208, in the edge regions E of the IDT 208, and form a boundary of the active region running parallel with the bus bars. The trench portions 210 slow down the acoustic velocity at edge of the active region to set up piston mode distribution, and thus suppress the transverse modes.

FIGS. 3A to 3C are graphs showing data from simulations, showing a comparison between admittance curves (complex FIG. 3A, and real FIG. 3B) and quality factor curves (Q-factor, FIG. 3C) of an acoustic wave device of the present disclosure with trench portions and a comparative example without trench portions. In particular, the graphs of FIGS. 3A to 3C include a solid line trace showing the simulation results for the acoustic wave device 200 of FIGS. 2A to 2E with a length l_{Trench} of the trench portions 210 equal to 1λ and a trench depth H_LTtr of 0.007λ, where λ is the wavelength of the main acoustic wave to be generated by the IDT 508. The dashed line trace is for the comparative example, which is identical to the acoustic wave device 200 of the solid line trace except that it does not include the trench portions.

As can be seen from the graphs of FIGS. 3A and 3B, many transverse modes are present in the dashed line trace of the comparative example. In the solid line trace for the acoustic wave device 200 with trench portions 210, on the other hand, the transverse modes are greatly suppressed.

It can therefore be seen from the previous diagrams and graphs that the inclusion of trench structures in an acoustic wave device can beneficially lead to a reduction in unwanted transverse modes. However, the inclusion of trench structures can cause problems during fabrication of the acoustic wave device. Typically these trench structures are formed in the piezoelectric layer using an etching process. This typically involves an etching mask being placed to cover all of the upper surface of the layer of piezoelectric material 206 except for the edge regions E where the trench portions 210 are to be formed. Once the etching mask is in position, the trenches are etched into the piezoelectric layer. Various types of etching processes may be used, for example any of: chemical etching, laser etching, dry etching, vapor phase etching, wet etching, and plasma etching. The etching process is controlled to set the depth h of the trench portions 210 cut into the layer of piezoelectric material 206, with the size and shape of the etching mask determining the width w of the trench portions 210 cut into the layer of piezoelectric material 206.

To achieve the beneficial effects of the trench structure demonstrated in FIGS. 3A-3C, the trench structures must have a certain depth. The deeper the trench, the more time that must be spent etching for the device to be fabricated. This time can be significant for each device, and a small increase in etching time can make a significant difference to the number of acoustic wave devices that can be produced in a given day.

It would therefore be beneficial if the trench depth for a device could be reduced whilst maintaining the beneficial effects of reducing transverse modes. The present application seeks to achieve this by employing an acoustic wave device with a different topology, specifically by including wider tip portions 520 for the electrode fingers.

### SUMMARY

According to one embodiment there is provided an acoustic wave device, comprising: a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material; a pair of interdigital transducer electrodes disposed on an upper surface of the layer of piezoelectric material, each interdigital transducer electrode including a bus bar, and a plurality of electrode fingers extending from the bus bar to the distal ends of the electrode fingers at an edge region of the interdigital transducer electrode; and trench portions located in the upper surface of the layer of piezoelectric material, said trench portions being overlapped by the edge regions of the interdigital transducer electrodes; the electrode fingers having a width at their distal end that is greater than the width of the rest of the electrode finger.

In one example the trench portions each have a depth relative to the upper surface of the layer of piezoelectric material of between about 0.0042 and 0.022, where A is the wavelength of an acoustic wave generated by the pair of interdigital transducer electrodes during operation.

In one example the trench portions each have a depth relative to the upper surface of the layer of piezoelectric material of about 15 nm.

In one example the trench portions are located in the areas of the upper surface of the layer of piezoelectric material that are overlapped by the edge regions of the interdigital transducer electrodes and are not covered by the material of the interdigital transducer electrodes.

In one example the trench portions extend discontinuously in the direction of propagation of an acoustic wave to be generated by the pair of interdigital transducer electrodes.

In one example the trench portions each have a length of between about 0.52 and 1λ, where λ is the wavelength of the acoustic wave to be generated.

In one example the bus bars of the pair of interdigital transducer electrodes are opposing and the plurality of electrode fingers of each interdigital transducer electrode extend towards the bus bar of the other electrode.

In one example the electrode fingers of each interdigital transducer electrode interleave with one another in an active region of the pair of interdigital transducer electrodes, and form gap regions between the ends of the fingers of one of the electrodes and the bus bar of the other electrode.

In one example the edge regions of the pair of interdigital transducer electrodes are located within the active region and on opposing sides of the active region.

In one example the active region includes a central region and the edge regions of the interdigital transducer electrodes, each edge region extending from the tips of the plurality of electrode fingers of one of the interdigital transducer electrodes towards the center of the central region.

In one example a duty factor of the pair of interdigital transducer electrodes in the edge regions of the interdigital transducer electrodes is larger than a duty factor of the pair of interdigital transducer electrodes in the central region of the active region.

In one example the duty factor at the distal end of the electrode fingers is between about 0.5 and 0.64.

In one example the duty factor at the distal end of the electrode fingers is 0.52.

In one example the portion of the interdigital transducer electrode with greater width is contiguous with one or more adjacent trench portions in the layer of piezoelectric material and has the same length as the length of the one or more trench portions.

In one example the bus bars of the pair of interdigital transducer electrodes are opposing and the plurality of electrode fingers of each interdigital transducer electrode extend towards the bus bar of the other electrode.

In one example the trench portions in the upper surface of the layer of piezoelectric material are also overlapped with at least part of the gap regions.

In one example the trench portions each have a length in a direction perpendicular to the direction of propagation of an acoustic wave to be generated by the pair of interdigital transducer electrodes that extends from the respective edge region to the bus bar of the other electrode.

In one example each of the interdigital transducer electrodes includes a second bus bar that is located within the gap region.

In one example the trench portions each have a length that extends from the respective edge region to the second bus bar of the other electrode.

In one example the layer of piezoelectric material is formed of a material selected from the group consisting of lithium tantalate, aluminum nitrate, lithium niobate, or potassium niobate.

In one example the layer of dielectric material includes silicon dioxide, or doped silicon material.

In one example the carrier substrate is formed of a material selected from the group consisting of silicon, aluminum nitride, silicon nitride, magnesium oxide spinel, magnesium oxide crystal, quartz, diamond, diamond like carbon, or sapphire.

In one example the carrier substrate comprises: a first layer of substrate comprising silicon, silicon carbide, sapphire, quartz, diamond, or diamond like carbon; and a second layer of substrate comprising aluminum nitride, silicon nitride, polycrystalline silicon, or amorphous silicon, the second layer of substrate having a lower surface disposed against an upper surface of the first layer of substrate, and an upper surface disposed against the lower surface of the layer of dielectric material.

In one example each interdigital transducer electrode is formed from a single layer of etch resistant material.

In one example the etch resistant material is selected from the group consisting of copper, platinum, tungsten, molybdenum, ruthenium, iridium, gold and silver.

In one example each interdigital transducer electrode is formed from one or more lower layers of material and an upper layer of etch resistant material.

In one example the etch resistant material is selected from the group consisting of copper, platinum, tungsten, molybdenum, ruthenium, iridium, gold and silver.

In one example each interdigital transducer electrode includes a mask layer on the upper surface of the interdigital transducer electrode.

In one example the mask layer is a layer of chromium.

In one example the acoustic wave device further comprises a protective layer disposed over the upper surfaces of the pair of interdigital transducer electrodes and the layer of piezoelectric material.

In one example the protective layer is formed from one or more of the group consisting of silicon nitride, silicon oxynitride and silicon dioxide.

According to another embodiment there is provided a radio frequency filter comprising at least one acoustic wave device, the acoustic wave device including: a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material; a pair of interdigital transducer electrodes disposed on an upper surface of the layer of piezoelectric material, each interdigital transducer electrode including a bus bar, and a plurality of electrode fingers extending from the bus bar to the distal ends of the electrode fingers at an edge region of the interdigital transducer electrode; and trench portions located in the upper surface of the layer of piezoelectric material, said trench portions being overlapped by the edge regions of the interdigital transducer electrodes; the electrode fingers having a width at their distal end that is greater than the width of the rest of the electrode finger. The at least one acoustic wave device can include a first acoustic wave device and a second acoustic wave device. The plurality of electrode fingers of the first acoustic wave device can have a different duty cycle at their distal ends than the plurality of electrode fingers of the second acoustic wave device. The trench portions of the first acoustic wave device can have a same trench depth as the trench portions of the second acoustic wave device.

According to another embodiment there is provided an electronics module comprising at least one radio frequency filter that includes at least one acoustic wave device, the at least one acoustic wave device including: a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material; a pair of interdigital transducer electrodes disposed on an upper surface of the layer of piezoelectric material, each interdigital transducer electrode including a bus bar, and a plurality of electrode fingers extending from the bus bar to the distal ends of the electrode fingers at an edge region of the interdigital transducer electrode; and trench portions located in the upper surface of the layer of piezoelectric material, said trench portions being overlapped by the edge regions of the interdigital transducer electrodes; the electrode fingers having a width at their distal end that is greater than the width of the rest of the electrode finger.

Still other aspects, embodiments, and advantages of these exemplary aspects and embodiments are discussed in detail below. Embodiments disclosed herein may be combined with other embodiments in any manner consistent with at least one of the principles disclosed herein, and references to “an embodiment,” “some embodiments,” “an alternate embodiment,” “various embodiments,” “one embodiment” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF THE DRAWINGS

Various aspects of at least one embodiment are discussed below with reference to the accompanying figures, which are not intended to be drawn to scale. The figures are included to provide illustration and a further understanding of the various aspects and embodiments, and are incorporated in and constitute a part of this specification, but are not intended as a definition of the limits of the disclosure. In the figures, each identical or nearly identical component that is illustrated in various figures is represented by a like numeral. For purposes of clarity, not every component may be labeled in every figure. In the figures:

FIG. 1A is a cross sectional side view of an acoustic wave device of the prior art;

FIG. 1B is a plan view of the acoustic wave device of FIG. 1A;

FIG. 2A is a plan view of an acoustic wave device of the prior art;

FIG. 2B is a cross sectional view of the acoustic wave device of FIG. 2A;

FIG. 2C is a cross sectional view of the acoustic wave device of FIG. 2A;

FIG. 2D is a cross sectional view of the acoustic wave device of FIG. 2A;

FIG. 2E is a cross sectional view of the acoustic wave device of FIG. 2A;

FIG. 3A is a graph showing a comparison of admittance curves of an acoustic wave device of FIG. 2A and an acoustic wave device of FIG. 1A;

FIG. 3B is a graph showing a comparison of admittance curves of an acoustic wave device a of FIG. 2A and an acoustic wave device of FIG. 1A;

FIG. 3C is a graph showing a comparison of quality factor curves of an acoustic wave device of FIG. 2A and an acoustic wave device of FIG. 1A;

FIG. 4 is a schematic diagram showing the how variations in the width of the IDT fingers (w) compared to the width of the spacing between the same part of the IDT fingers (p) sets the duty factor (DF).

FIG. 5A is a plan view of an acoustic wave device according to aspects of the present disclosure;

FIG. 5B is a cross sectional view of the acoustic wave device of FIG. 5A;

FIG. 5C is a cross sectional view of the acoustic wave device of FIG. 5A;

FIG. 5D is a cross sectional view of the acoustic wave device of FIG. 5A;

FIG. 5E is a cross sectional view of the acoustic wave device of FIG. 5A;

FIG. 6 is a graph showing a comparison of how variations in trench depth (H_LTtr) and Duty Factor (DF) effect wave velocity speeds;

FIG. 7 is a graph showing a comparison of admittance curves of an acoustic wave device a of FIG. 5A compared to acoustic wave devices of alternative edge Duty Factors and trench depths;

FIG. 8A is a plan view of an acoustic wave device according to aspects of the present disclosure;

FIG. 8B is a cross sectional view of the acoustic wave device of FIG. 8A;

FIG. 8C is a cross sectional view of the acoustic wave device of FIG. 8A;

FIG. 8D is a cross sectional view of the acoustic wave device of FIG. 8A;

FIG. 8E is a cross sectional view of the acoustic wave device of FIG. 8A;

FIG. 9A is a plan view of an acoustic wave device according to aspects of the present disclosure;

FIG. 9B is a cross sectional view of the acoustic wave device of FIG. 9A;

FIG. 9C is a cross sectional view of the acoustic wave device of FIG. 9A;

FIG. 10A is a plan view of an acoustic wave device according to aspects of the present disclosure;

FIG. 10B is a cross sectional view of the acoustic wave device of FIG. 10A;

FIG. 10C is a cross sectional view of the acoustic wave device of FIG. 10A;

FIG. 11 is a plan view of an acoustic wave device according to aspects of the present disclosure;

FIG. 12 is a plan view of an acoustic wave device according to aspects of the present disclosure;

FIG. 13 is a block diagram of one example of a filter module that can include

FIG. 13′ is a block diagram of one example of a die including an acoustic wave filter according to certain aspects;

FIG. 14 is a block diagram of one example of a front-end module that can include one or more filter modules including acoustic wave devices according to aspects of the present disclosure;

FIG. 15 is a block diagram of one example of a wireless device including the front-end module of FIG. 14.

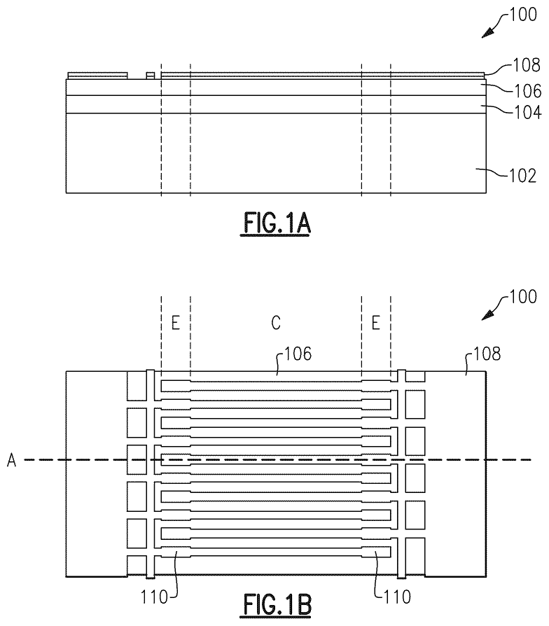

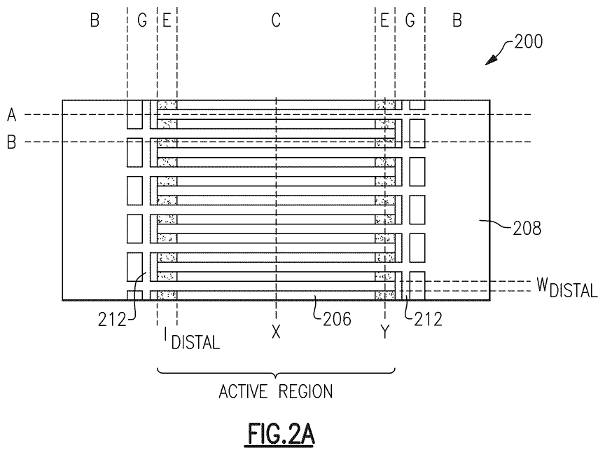

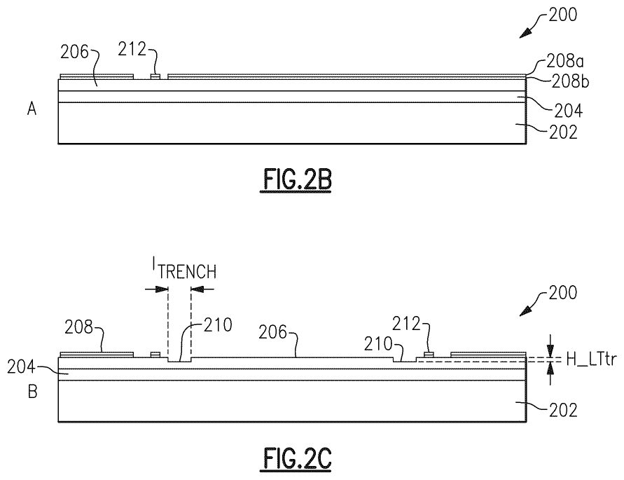

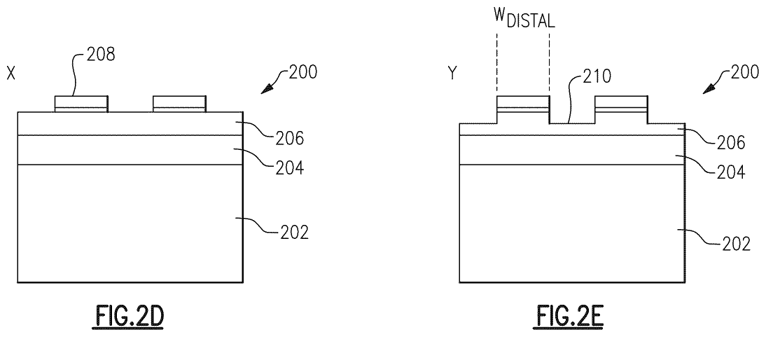

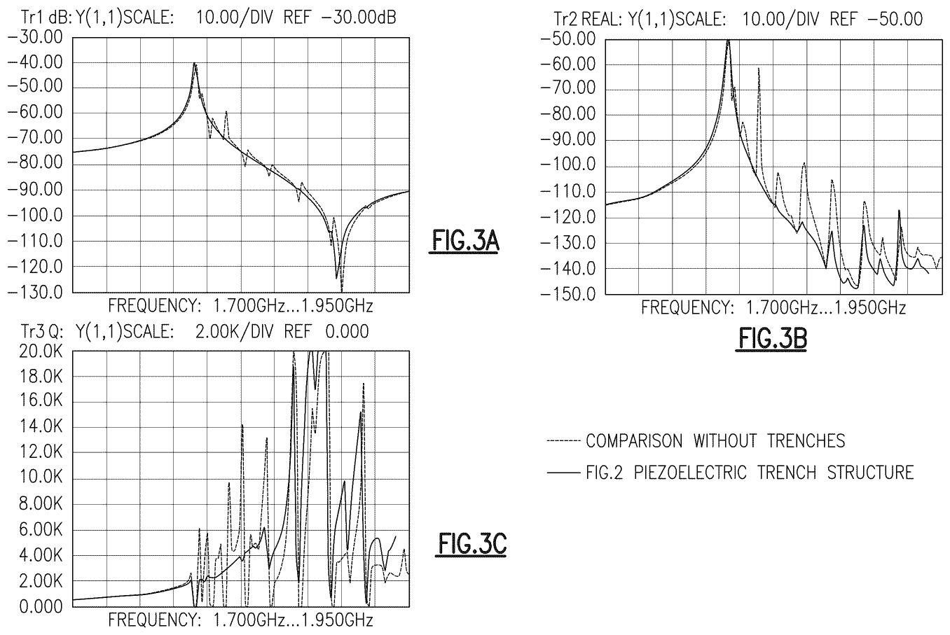

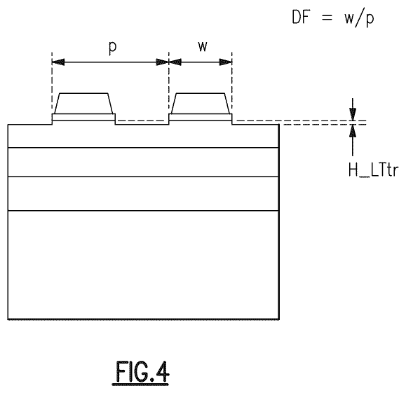

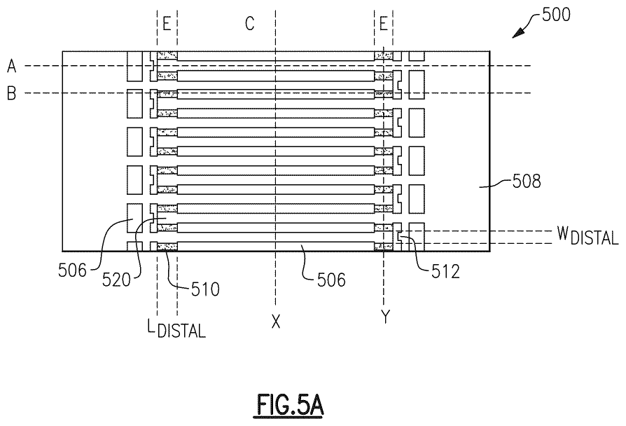

### DETAILED DESCRIPTION

An acoustic wave device, a radio frequency filter, and an electronics module are provided. The acoustic wave device comprises a layer of carrier substrate, a layer of dielectric material, a layer of piezoelectric material, a pair of interdigital transducer electrodes, each interdigital transducer electrode including a bus bar and a plurality of electrode fingers extending from the bus bar to the distal ends of the electrode fingers at an edge region of the interdigital transducer electrode, and trench portions located in the upper surface of the layer of piezoelectric material, said trench portions being overlapped by the edge regions of the interdigital transducer electrodes, the electrode fingers having a width at their distal end that is greater than the width of the rest of the electrode finger. The acoustic wave device provides effective suppression of transverse modes.

It is to be appreciated that embodiments of the methods and apparatuses discussed herein are not limited in application to the details of construction and the arrangement of components set forth in the following description or illustrated in the accompanying drawings. The methods and apparatuses are capable of implementation in other embodiments and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

The disclosure is described below through embodiments of the acoustic wave device, in particular surface acoustic wave (SAW) devices. However, as would be understood by the skilled person, various different excitation modes are possible in acoustic wave filters and devices, particularly MPS devices. As well as surface acoustic waves other types of acoustic wave are possible such as boundary acoustic waves and guided acoustic waves. References to surface acoustic waves and surface acoustic wave (SAW) devices in the following description are not intended to limit the disclosure from including or covering other possible types of acoustic waves and acoustic wave devices.

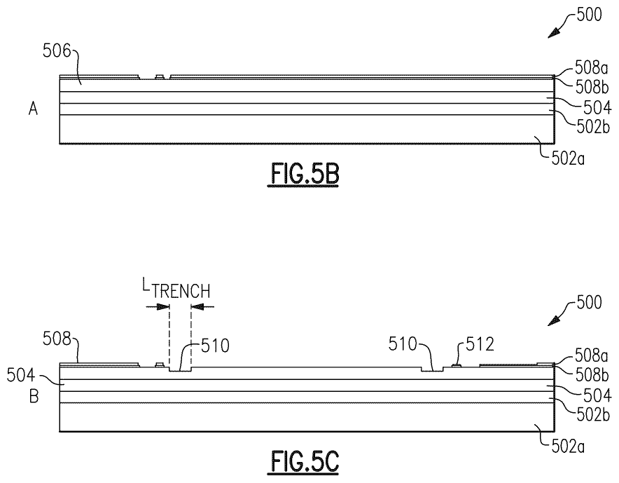

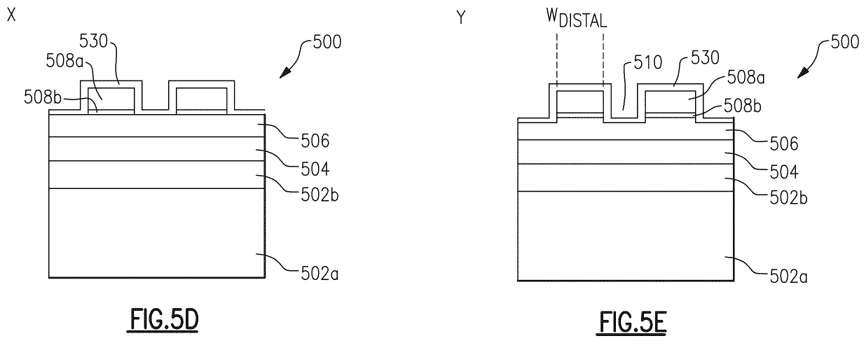

FIGS. 5A to 5E show an acoustic wave device 500 (e.g., an acoustic resonator) in an embodiment of the present disclosure. The acoustic wave device 500 includes a carrier substrate 502a and 502b, a layer of dielectric material 504, a layer of piezoelectric material 506, an IDT 508 with an upper layer 508a and a lower layer 508b, and trench portions 510 located in the upper surface of the layer of piezoelectric material. The device 500 may optionally include a protective layer 530.

It is to be understood that further, unspecified layers may also be included below the acoustic wave device 500 (i.e. below carrier substrate layer 502a) or above the acoustic wave device 500 (i.e. above the IDT layer 508a or protective layer 530). This may occur when the acoustic wave device 500 is used in a component of another device, such as a SAW filter, to hold the component in place whilst in use.

The carrier substrate may be formed of a single layer 502a. The carrier substrate may be formed of a material having a lower coefficient of linear expansion and/or a higher thermal conductivity and/or a higher toughness or mechanical strength than the piezoelectric material. The carrier substrate 502a may both increase the mechanical robustness of the piezoelectric material during fabrication of the SAW device and increase manufacturing yield, as well as reducing the amount by which operating parameters of the SAW device change with temperature during operation. The carrier substrate 502a may be referred to as a high impedance support substrate.

The carrier substrate may be formed of two layers, 502a and 502b, with the second layer of substrate 502b being disposed between the first layer of substrate 502a and the dielectric layer 504. The second layer 502b may act as a trap-rich layer, and can be used to improve the effective resistivity of the substrate layers.

The first layer of substrate 502a may comprise silicon, silicon carbide, sapphire, quartz, diamond, or diamond like carbon. The second layer of substrate 502b may comprise aluminum nitride (AlN), silicon nitride (Si₃N₄), polycrystalline silicon (poly-Si), or amorphous silicon (A-Si).

The dielectric layer may be disposed with a surface disposed against a surface of the substrate layer 502a (or 502b if this optional layer is included). The dielectric layer may comprise silicon dioxide (SiO₂) or doped silicon material such as F doped SiO2 or Ti doped SiO2.

The piezoelectric layer 506 may be disposed with a surface disposed against a surface of the dielectric layer 504. Any piezoelectric material may be used as the layer of piezoelectric material 506, for example, including but not limited to lithium tantalate (LiTaO₃), aluminum nitrite (AlN), lithium niobate (LiNbO3), or potassium niobate (KNbO3).

An interdigital transducer (IDT) 508 is disposed on top of the layer of piezoelectric material 506 and is configured to generate a surface acoustic wave in the multilayer piezoelectric substrate. In use, the IDT 508 excites a main acoustic wave having a wavelength λ along a surface of the multilayer piezoelectric substrate. The acoustic wave is concentrated in the top two layers (the layer of dielectric material 504 and layer of piezoelectric material 506). The carrier substrate 502 (in this case silicon) may have a high impedance, meaning the acoustic wave is reflected at the boundary between the carrier substrate 502 and the layer of dielectric material 504, confining the surface acoustic wave in the top two layers. In some embodiments, the thickness of the layer of dielectric material 504 may be between 0.1λ and 1λ, and the thickness of the layer of piezoelectric material 506 may be between 0.1λ and 1λ. It is to be understood that the dimensions above are only examples and may be set at different values in different embodiments of acoustic wave devices to achieve different design goals.

Any type of IDT may be used as the IDT 508 in the acoustic wave device 500. For example, a typical IDT will include a pair of interlocking comb shaped IDT electrodes. Each electrode of the IDT typically includes a bus bar and a plurality of electrode fingers that extend perpendicularly from the bus bar. Typically the distance between the central point of each adjacent electrode finger extending from the same bus bar is equal to the wavelength λ of the surface acoustic wave generated. The bus bars of each of the pair or IDT electrodes are parallel and opposing each other, and the plurality of electrode fingers of each IDT electrode extend towards to the bus bar of the opposing electrode, such that the electrode fingers interlock, typically with a distance of λ/2 between the center of each adjacent electrode finger extending from opposite bus bar. The main surface acoustic wave generated by the IDT travels perpendicular to the lengthwise direction of the IDT electrode fingers, and parallel to the lengthwise direction of the IDT bus bars.

Regardless of the type of IDT used, the IDT 508 has an active region defined as the region that the fingers of each interdigital transducer electrode interleave with one another. The surface acoustic wave is generated in the active region of the IDT. The active region of the IDT includes a central region and two edge regions. The central region is labeled by the letter C in FIG. 5A and the edge regions are labeled by the letter E. Each edge region E extends from the tips of the plurality of fingers of one of the electrodes towards the center of the central region C. In other words, the edge regions E include end portions of the IDT electrode fingers, and the central region C is sandwiched between the edge regions. The IDT also includes gap regions located between the ends of the fingers of one of the electrodes and the bus bar of the other electrode. The dashed lines in FIG. 5A show the boundaries between the above described regions.

In the embodiment of FIG. 5A, the IDT electrodes 508 each include a second bus bar 512. The second bus bars 512 extend parallel to the bus bars, and are located adjacent to the edge regions E of the IDT 508. The second bus bars 512 are thinner than the bus bars, and may be referred to as “mini bus bars”. The mini bus bars result in the transverse modes being suppressed more effectively However, in some embodiments these mini bus bars may be omitted. Whilst the suppression of the transverse modes is improved when the acoustic wave device includes the mini bus bars 512, compared to when the mini bus bars are omitted, the inclusion of mini bus bars 512 is optional.

In the embodiments of FIGS. 5A to 5E a double layer IDT 508 is used, with an upper IDT layer 508a and a lower IDT layer 508b. However single layer IDTs may also be used. In general various IDT structures are possible, as would be understood by the skilled person, for example double electrode IDTs, or IDTs with dummy electrode fingers may be used. Specific IDT configurations will be discussed in more detail later, taking into consideration the method of manufacture of the device.

The interdigital transducer electrode may be formed from a single layer of etch resistant material, chosen to protect the exposed sections of the IDT 508 during an etching process. A multilayer IDT may be used with an upper IDT layer 508a and a lower IDT layer 508b. In embodiments with such IDT configurations, a high density IDT material that is etch resistant is chosen as the upper IDT layer 508a. The high density upper IDT layer means that the exposed sections of the IDT are protected during the etching process, even when not covered by an etching mask. The high density upper IDT layer also means that the surface of the piezoelectric material underneath the IDT is protected and therefore not removed during the etching process.

The high density IDT material of the upper IDT layer may be any of copper Cu, platinum Pt, tungsten W, molybdenum Mo, ruthenium Ru, iridium Ir, gold Au and silver Ag. Preferably, copper is chosen as the high density material for the upper IDT layer 508a, as it is resistant to etching chemicals as well as being highly conductive, meaning resistive loss is reduced.

The lower IDT layer 508b can include materials that are not etch resistant, such as aluminum Al, due to the high density upper IDT layer. However, other materials that are etch resistant may still be used as the lower layer in some embodiments, for example a copper Cu lower layer. In some embodiments, the IDT may include multiple lower IDT layers underneath the upper IDT layer.

In a specific embodiment, a high density Molybdenum Mo layer may be used as the upper IDT layer 508a, and lower density but higher conductivity aluminum Al may be used as the lower layer 508b.

In general, the IDT may be formed through one or more of mask printing, deposition such as physical vapor deposition, electroplating, a lift-off process, a dry etching process, or the like. A lift-off process is preferred.

The acoustic wave device 500 further includes trench structures in the layer of piezoelectric material for suppressing the transverse modes. Trench portions 510 are located in the upper surface of the layer of piezoelectric material. The trench portions 510 overlap with the edge regions E of the IDT electrodes 508. In other words, the trench portions 510 are located within the active region of the IDT 508, in the edge regions E of the IDT 508, and form a boundary of the active region running parallel with the bus bars. The trench portions 510 slow down the acoustic velocity at edge of the active region to set up piston mode distribution, and thus suppress the transverse modes. The trench structures may preferably have a depth relative to the upper surface of the layer of piezoelectric material of between about 0.004λ and 0.02λ, where λ is the wavelength of an acoustic wave generated, or alternatively a depth of around 15 nm. The trench portions may preferably have a length (i.e. extending lengthwise between the central and edge regions of the device, perpendicular to the direction in which waves are generated whilst in use) of between about 0.5λ and 1λ, where λ is the wavelength of the acoustic wave to be generated.

As can be seen from FIG. 5A, the trench portions 510 extend parallel to the bus bars, in the direction of propagation of the main acoustic wave generated by the IDT 508. However, the trench portions are only present in the sections of the upper surface of the layer of piezoelectric material 506 that are overlapped by the edge regions E of the IDT 508 and are not covered by the material of the IDT 508. In other words, the trench portions 510 are only cut into the surface of the layer of piezoelectric material 506 that is exposed after the IDT 508 has been formed on the layer of piezoelectric material 506. The trench portions 510 are not cut into the sections of the layer of piezoelectric material 506 covered by the IDT 508, meaning the trench portions 510 do not run underneath the IDT 508. The layer of piezoelectric material 506 remains at full thickness underneath the IDT 508. This is best seen in FIG. 5E, showing the trench portions 510 cut into the upper surface of the layer of piezoelectric material 506 not covered by the IDT 508, and not cut into the upper surface of the layer of piezoelectric material 506 covered by the IDT 508. A comparison of the cross-sectional views of FIGS. 5B and 5C also shows this. Therefore the trench portions 510 can be described as extending discontinuously in the direction of propagation of the main acoustic wave generated by the IDT 508 (along the line marked Y in FIG. 5A).

The trench portions 510 can be formed in this way by etching the piezoelectric substrate. In particular, the trenches portions 510 may be etched after the formation of the IDT 508 on the upper surface of the layer of piezoelectric material 506, with the IDT preventing etching of the layer of piezoelectric material 506 underneath the IDT.

It can be seen in FIG. 5A that the electrode fingers of the IDT 508 are not of uniform width. Instead, the electrode fingers includes wider tip portions 520 which are sections of each of the plurality of electrode fingers in the IDT electrodes 508 that have a width in a direction perpendicular to the extension of the electrode fingers that is larger in the edge regions E of the IDT electrodes than in the central regions C of the IDT electrodes. The wider tip portions 520 are located in the edge region E of each IDT electrode. In other words, the distal ends of the plurality of electrode fingers in each IDT electrode (the ends furthest from the respective bus bar) have an increased width, W_{Distal}. The wider tip portions 520 are also located at the sections of each IDT electrode that overlap with the edge region E of the other IDT electrode. The widths of the plurality of electrode fingers of each IDT electrode are therefore larger in both the edge region E of that IDT electrode and the edge region E of the other IDT electrode, as best seen in the view of FIG. 5A.

Put another way, a duty factor (DF) of the pair of IDT electrodes 508 in the edge regions E is larger than a duty factor of the pair of interdigital transducer electrodes in the central region C, best seen in the comparison of FIGS. 5D and 5E. The duty factor at this distal end of the electrode fingers may preferably be between about 0.5 and 0.64, such as 0.52. The reasoning as to why the increased width of the wider tip portions 520 leads to a larger DF compared to the thinner central portion of the electrode fingers can be understood from the Duty Factor diagram shown in FIG. 4. As can be seen from FIG. 5E, the trench portions 510 that are cut out of the layer of piezoelectric material 506 extend a smaller distance in the direction of propagation of the acoustic wave to be generated by the IDT 508, due to the reduced separation between the electrode fingers in the edge regions E. The trench portions 510 do not extend underneath the sections of the plurality of electrode fingers in the edge region E.

The acoustic wave device 500 may additionally include an optional protective layer 530 disposed on top of the upper surfaces of the pair of interdigital transducer electrodes and the layer of piezoelectric material. This protective layer is shown in FIGS. 5D and 5E. The protective layer is applied to the acoustic wave device 500 after the trench portions 510 have been formed in the layer of piezoelectric material 506 (e.g. via etching). The protective layer helps to protect the IDT from chemical and physical damage during fabrication processing, and protects the IDT from humidity or other chemical damage after fabrication. Additionally, the protective layer 530 can help to protect the IDT from mechanical migration or loss of material in the upper piezoelectric 506 or IDT layers 508 when in use. The protective layer 530 may comprise silicon nitride (SiN), silicon oxynitride (SiON) and silicon dioxide (SiO₂).

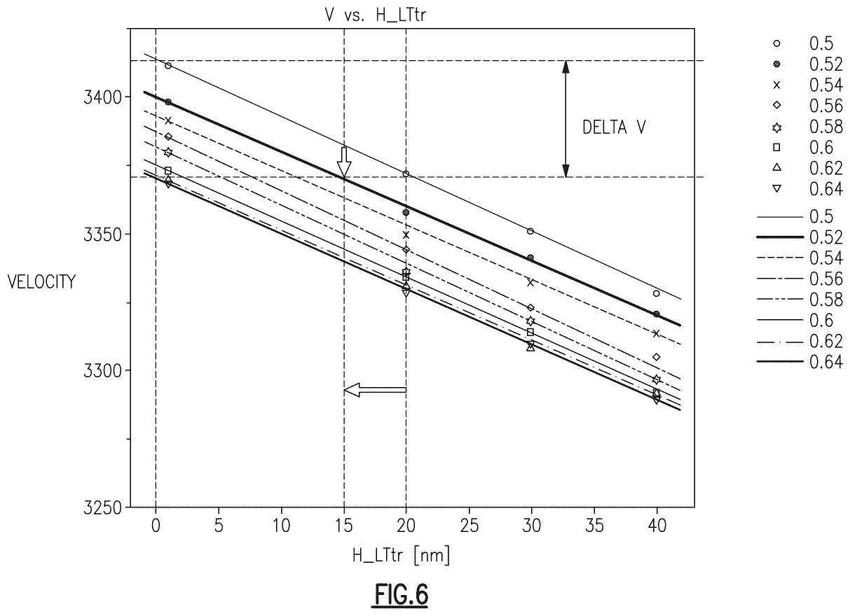

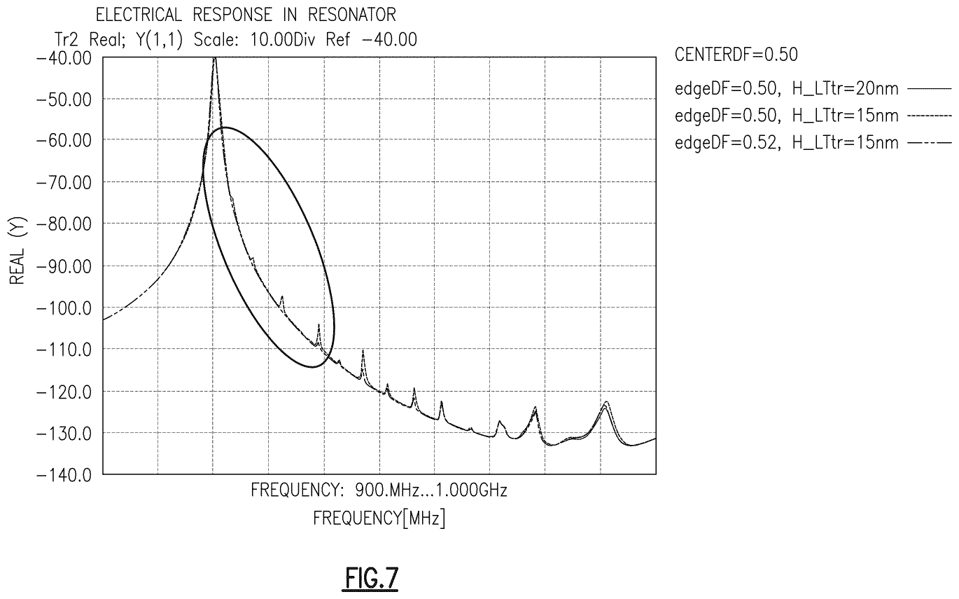

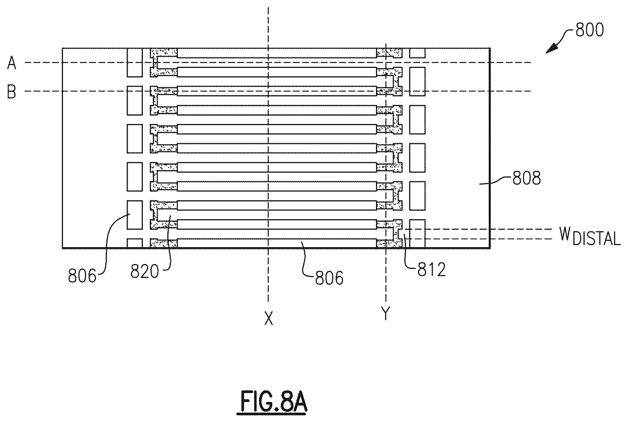

FIG. 6 is a graph demonstrating the effect on the wave velocity in the edge regions produced by the altering trench depth H_LTtr for various SAW devices of varying edge DF. Each straight line represents the H_LTtr vs V relationship for a SAW device of a particular edge DF value. As shown in this diagram, the inventors of the present disclosure have discovered that by increasing the edge DF (i.e. by increasing the width W Distal of the wider tip portions), the edge velocity can be maintained whilst trench depth H_LTtr is decreased.

FIG. 7 is a graph showing a comparison of admittance curves of acoustic wave devices with varying edge duty factors and trench depths. It is seen that on the right side of the peak that reducing the trench depth H_LTtr from 20 nm to 15 nm without altering the edge DF results in unwanted transverse mode spikes. However, by simultaneously increasing the edge DF (i.e. by including wider tip portions 520) it is seen that these transverse spikes can be avoided even with the reduction in trench depth.

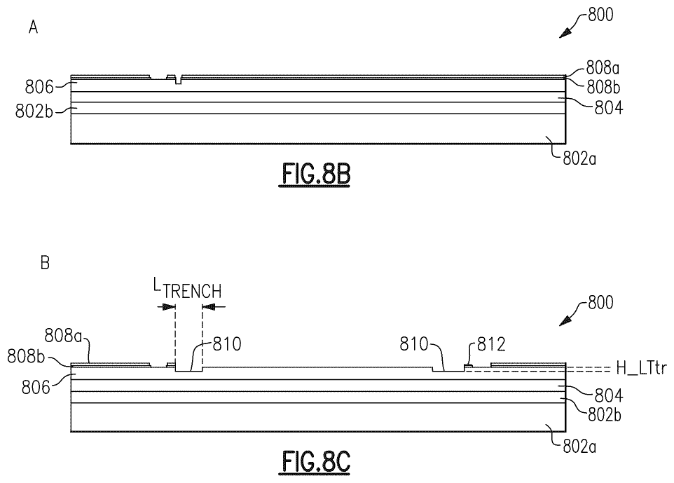

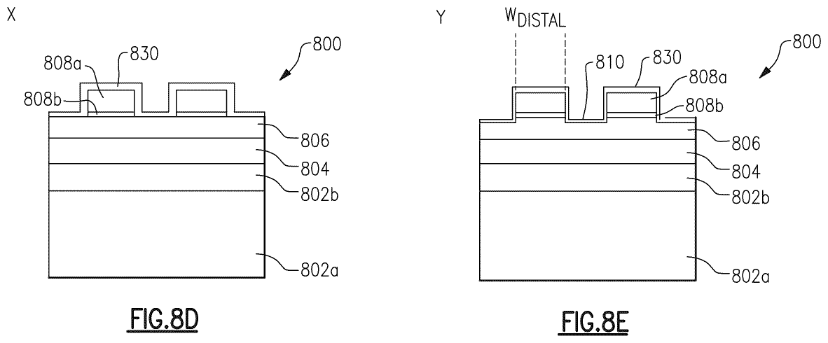

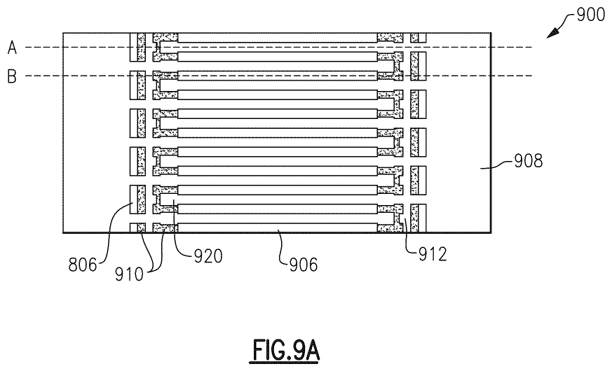

FIGS. 8A to 8E show an acoustic wave device 800 in another embodiment of the present disclosure. The acoustic wave device 800 includes a carrier substrate 802a, 802b, a layer of dielectric material 804, a layer of piezoelectric material 806, an IDT with an upper layer 808a and a lower layer 808b, and trench portions 810 located in the upper surface of the layer of piezoelectric material. The acoustic wave device 800 can also include a protective layer 830. The acoustic wave device 800 is identical to the acoustic wave device 500 of FIGS. 5A to 5E except that the trench portions extend further lengthwise along the acoustic wave device 800, and the two trench regions on either side of the wider tip portions 820 are connected by another trench region etched into the piezoelectric layer 806. The difference between acoustic wave device 500 and acoustic wave device 800 is best seen by comparing FIG. 5A with FIG. 8A, and FIG. 5B with FIG. 8B.

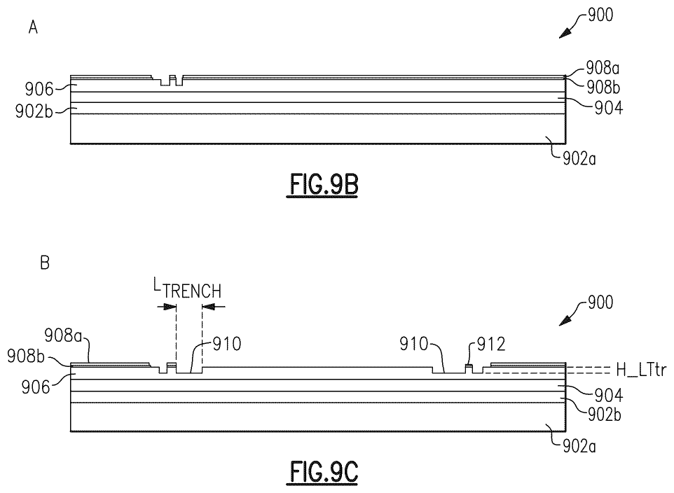

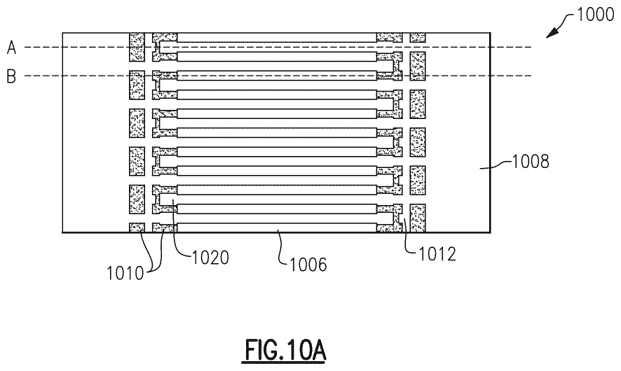

FIGS. 9A to 9C show an acoustic wave device 900 in another embodiment of the present disclosure. The acoustic wave device 900 includes a carrier substrate 902a, 902b, a layer of dielectric material 904, a layer of piezoelectric material 906, an IDT with an upper layer 908a and a lower layer 908b, and trench portions 910 located in the upper surface of the layer of piezoelectric material. The acoustic wave device 900 can also include a protective layer 930. The acoustic wave device 900 is identical to the acoustic wave device 800 of FIGS. 8A to 8E except that an additional trench portion is included in the mini bus bar regions. This additional trench portion is shown as being approximately half the total length of the mini bus bar, although this proportion could be varied (e.g. ⅓ of the total mini bus bar length or ⅔ of the total length). The mini bus bar trench is located on the side of the mini bus bar closest to the wider tip portions 920 and other trench portions 910.

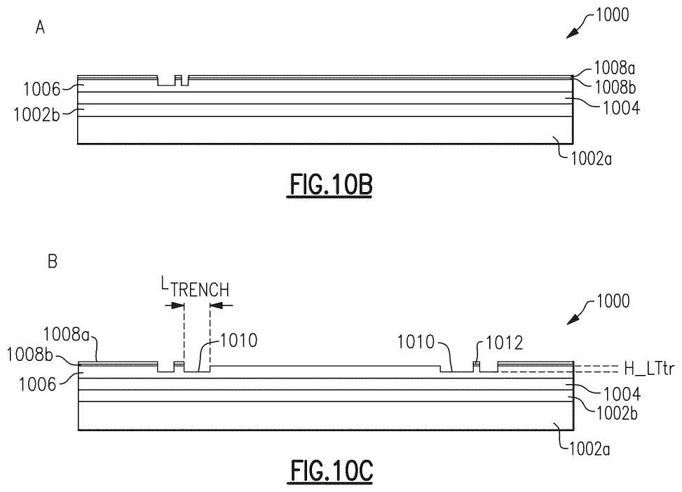

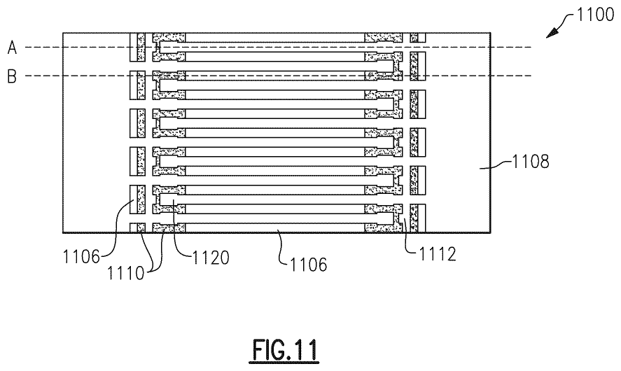

FIGS. 10A to 10C show an acoustic wave device 1000 in another embodiment of the present disclosure. The acoustic wave device 1000 includes a carrier substrate 1002a, 1002b, a layer of dielectric material 1004, a layer of piezoelectric material 1006, an IDT with an upper layer 1008a and a lower layer 1008b, and trench portions 1010 located in the upper surface of the layer of piezoelectric material. The acoustic wave device 1000 can also include a protective layer (not shown). The acoustic wave device 1000 is identical to the acoustic wave device 800 of FIGS. 8A to 8E except that an additional trench portion is included in the mini bus bar regions which is the entire length of the mini bus bar.

FIG. 11 shows an acoustic wave device 1100 in another embodiment of the present disclosure. The acoustic wave device 1100 includes a carrier substrate 1102a, 1102b, a layer of dielectric material 1104, a layer of piezoelectric material 1106, an IDT with an upper layer 1108a and a lower layer 1108b, and trench portions 1110 located in the upper surface of the layer of piezoelectric material. The acoustic wave device 1100 can also include a protective layer (not shown). The acoustic wave device 1100 is identical to the acoustic wave device 900 of FIGS. 9A to 9C except that the acoustic wave device 1100 includes a longer trench region 1110. In the acoustic wave device 900, the trench region extends from the location of the central region beginning where the wider tip portion 920 meets the rest of the electrode finger. In acoustic wave device 1100, the trench region 1110 extends even further towards the central region leading to a longer trench region 1110.

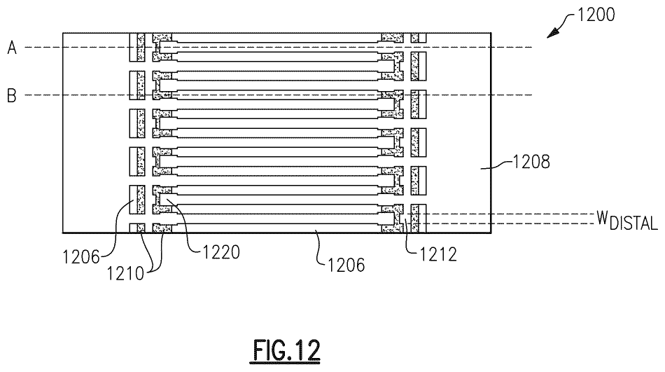

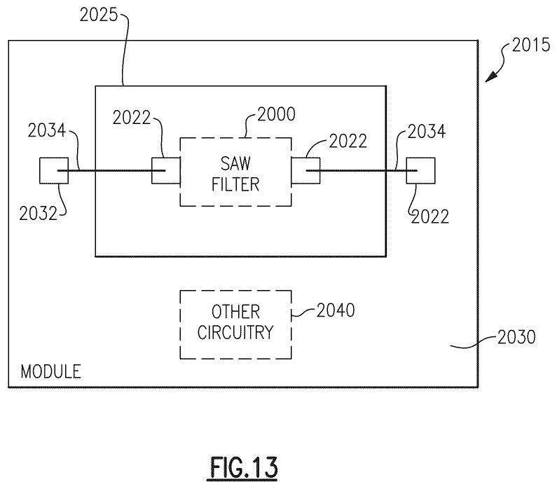

FIG. 12 shows an acoustic wave device 1200 in another embodiment of the present disclosure. The acoustic wave device 1200 includes a carrier substrate 1202a, 1202b, a layer of dielectric material 1204, a layer of piezoelectric material 1206, an IDT with an upper layer 1208a and a lower layer 1208b, and trench portions 1210 located in the upper surface of the layer of piezoelectric material. The acoustic wave device 1200 can also include a protective layer (not shown). The acoustic wave device 1200 is identical to the acoustic wave device 900 of FIGS. 9A to 9C except that the acoustic wave device 1200 includes a shorter trench region 1210. In the acoustic wave device 900, the trench region extends from the location of the central region beginning where the wider tip portion 920 meets the rest of the electrode finger. In acoustic wave device 1200, the trench region 1210 does not extend as far towards the central region leading to a shorter trench region 1210.

The various structures provided in FIGS. 8 to 12 can provide advantages over the structure given in FIG. 5. The removal of material from the piezoelectric layer near the edge regions in these additional structures can help in further suppressing the transverse modes.

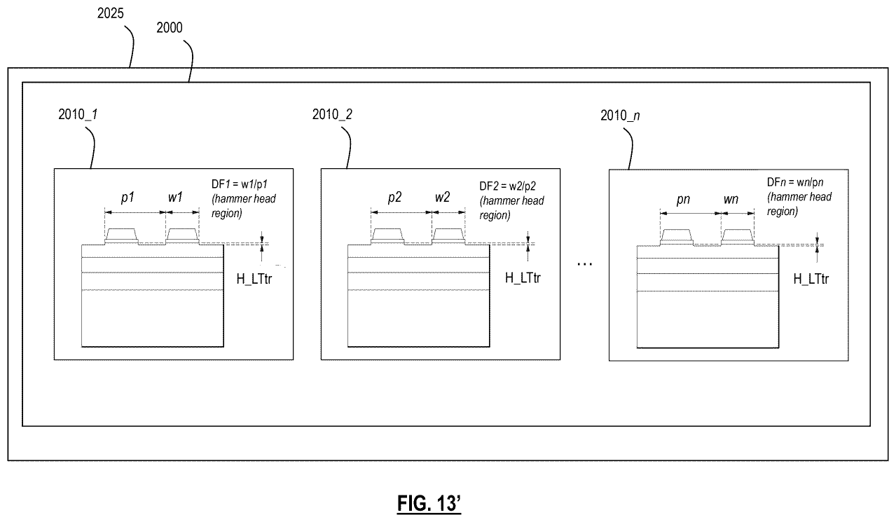

Examples an embodiments of acoustic wave devices discussed herein can be implemented in a variety of packaged modules. Some example packaged modules will now be discussed in which any suitable principles and advantages of the acoustic wave devices discussed herein can be implemented. FIGS. 13, 14, and 15 are schematic block diagrams of illustrative packaged modules and devices according to certain embodiments.

As discussed above, acoustic wave devices, such as those of FIGS. 5, 8, 9, 10, 11, and 12, can be used in radio frequency (RF) filters. In turn, an RF filter such as a SAW filter may be incorporated into and packaged as a module that may ultimately be used in an electronic device, such as a wireless communications device, for example. FIG. 13 is a block diagram illustrating one example of a module 2015 including a SAW filter 2000. The SAW filter 2000 may be implemented on one or more die(s) 2025 including one or more connection pads 2022.

The SAW filter die 2025 can include a plurality of acoustic wave devices (e.g., acoustic resonators) such as those of FIG. 5, 8, 9, 10, 11, or 12, which can be connected to form the SAW filter 2000.

According to certain embodiments, the SAW filter die 2025 can include a plurality of acoustic wave devices, where each of the acoustic wave devices have trench portions with the same trench depth H_LTtr, but where at least some of the acoustic wave devices on the die 2025 have different duty factors (DFs) in hammer head regions that at least partially overlap with the trench portions.

For example, FIG. 13′ shows an embodiment a SAW filter die 2025 including a saw filter 2000 with a plurality of SAW devices 2010_1-2010_n (e.g., acoustic resonators), where each SAW device has a common trench depth H_LTtr in its respective trench portions but a different duty factor (DF) in its respective hammer head regions.

Referring to FIGS. 4, 5, and 13′ for the purposes of illustration, in some embodiments each SAW device 2010_1-2010_n of FIG. 13′ can be an instance of the SAW device 500 of FIG. 5A, where each instance has trench portions 510 with the same trench depth H_LTtr across the die 2025, but where each instance has a different duty factor (DF) in its hammer head regions (or at their distal ends), which overlap with the trench portions 510 in the edge region E.

In this manner, the common trench depth H_LTtr can provide the coarse tuning of transverse mode suppression for the SAW filter 2000, while the differential DFs across the resonators 2010_1-2010_n can provide resonator by resonator fine tuning of transverse mode suppression. This can be beneficial for manufacturing purposes because it can be relatively difficult during manufacturing to achieve differential piezo trench depths H_LTtr across SAW devices 2010 on the die, whereas it can be relatively less difficult to achieve differential DFs across the SAW devices 2010 using photo mask layout.

For example, the SAW filter 2000 may include a connection pad 2022 that corresponds to an input contact for the SAW filter and another connection pad 2022 that corresponds to an output contact for the SAW filter. The packaged module 2015 includes a packaging substrate 2030 that is configured to receive a plurality of components, including the die 2025. A plurality of connection pads 2032 can be disposed on the packaging substrate 2030, and the various connection pads 2022 of the SAW filter die 2025 can be connected to the connection pads 2032 on the packaging substrate 2030 via electrical connectors 2034, which can be solder bumps or wirebonds, for example, to allow for passing of various signals to and from the SAW filter 2000. The module 2015 may optionally further include other circuitry die 2040, for example, one or more additional filter(s), amplifiers, pre-filters, modulators, demodulators, down converters, and the like, as would be known to one of skill in the art of semiconductor fabrication in view of the disclosure herein. In some embodiments, the module 2015 can also include one or more packaging structures to, for example, provide protection and facilitate easier handling of the module 2015. Such a packaging structure can include an overmold formed over the packaging substrate 2030 and dimensioned to substantially encapsulate the various circuits and components thereon.

Various examples and embodiments of the SAW filter 2000 can be used in a wide variety of electronic devices. For example, the SAW filter 2000 can be used in an antenna duplexer, which itself can be incorporated into a variety of electronic devices, such as RF front-end modules and communication devices.

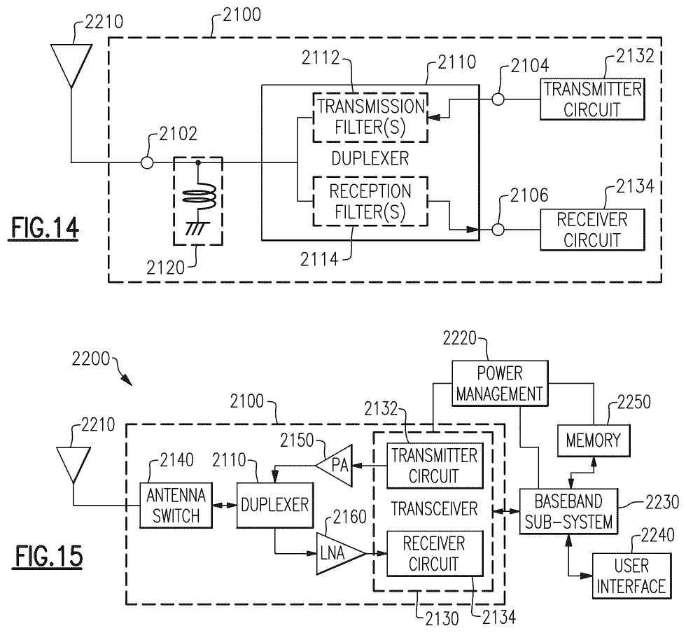

Referring to FIG. 14, there is illustrated a block diagram of one example of a front-end module 2100, which may be used in an electronic device such as a wireless communications device (e.g., a mobile phone) for example. The front-end module 2100 includes an antenna duplexer 2110 having a common node 2102, an input node 2104, and an output node 2106. An antenna 2210 is connected to the common node 2102.

The antenna duplexer 2110 may include one or more transmission filters 2112 connected between the input node 2104 and the common node 2102, and one or more reception filters 2114 connected between the common node 2102 and the output node 2106. The passband(s) of the transmission filter(s) are different from the passband(s) of the reception filters. Examples of the SAW filter 2000 can be used to form the transmission filter(s) 2112 and/or the reception filter(s) 2114. An inductor or other matching component 2120 may be connected at the common node 2102.

The front-end module 2100 further includes a transmitter circuit 2132 connected to the input node 2104 of the duplexer 2110 and a receiver circuit 2134 connected to the output node 2106 of the duplexer 2110. The transmitter circuit 2132 can generate signals for transmission via the antenna 2210, and the receiver circuit 2134 can receive and process signals received via the antenna 2210. In some embodiments, the receiver and transmitter circuits are implemented as separate components, as shown in FIG. 14, however, in other embodiments these components may be integrated into a common transceiver circuit or module. As will be appreciated by those skilled in the art, the front-end module 2100 may include other components that are not illustrated in FIG. 14 including, but not limited to, switches, electromagnetic couplers, amplifiers, processors, and the like.

FIG. 15 is a block diagram of one example of a wireless device 2200 including the antenna duplexer 2110 shown in FIG. 14. The wireless device 2200 can be a cellular phone, smart phone, tablet, modem, communication network or any other portable or non-portable device configured for voice or data communication. The wireless device 2200 can receive and transmit signals from the antenna 2210. The wireless device includes an embodiment of a front-end module 2100 similar to that discussed above with reference to FIG. 14. The front-end module 2100 includes the duplexer 2110, as discussed above. In the example shown in FIG. 15 the front-end module 2100 further includes an antenna switch 2140, which can be configured to switch between different frequency bands or modes, such as transmit and receive modes, for example. In the example illustrated in FIG. 15, the antenna switch 2140 is positioned between the duplexer 2110 and the antenna 2210; however, in other examples the duplexer 2110 can be positioned between the antenna switch 2140 and the antenna 2210. In other examples the antenna switch 2140 and the duplexer 2110 can be integrated into a single component.

The front-end module 2100 includes a transceiver 2130 that is configured to generate signals for transmission or to process received signals. The transceiver 2130 can include the transmitter circuit 2132, which can be connected to the input node 2104 of the duplexer 2110, and the receiver circuit 2134, which can be connected to the output node 2106 of the duplexer 2110, as shown in the example of FIG. 14.

Signals generated for transmission by the transmitter circuit 2132 are received by a power amplifier (PA) module 2150, which amplifies the generated signals from the transceiver 2130. The power amplifier module 2150 can include one or more power amplifiers. The power amplifier module 2150 can be used to amplify a wide variety of RF or other frequency-band transmission signals. For example, the power amplifier module 2150 can receive an enable signal that can be used to pulse the output of the power amplifier to aid in transmitting a wireless local area network (WLAN) signal or any other suitable pulsed signal. The power amplifier module 2150 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 2150 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 15, the front-end module 2100 may further include a low noise amplifier (LNA) module 2160, which amplifies received signals from the antenna 2210 and provides the amplified signals to the receiver circuit 2134 of the transceiver 2130.

The wireless device 2200 of FIG. 15 further includes a power management sub-system 2220 that is connected to the transceiver 2130 and manages the power for the operation of the wireless device 2200. The power management system 2220 can also control the operation of a baseband sub-system 2230 and various other components of the wireless device 2200. The power management system 2220 can include, or can be connected to, a battery (not shown) that supplies power for the various components of the wireless device 2200. The power management system 2220 can further include one or more processors or controllers that can control the transmission of signals, for example. In one embodiment, the baseband sub-system 2230 is connected to a user interface 2240 to facilitate various input and output of voice and/or data provided to and received from the user. The baseband sub-system 2230 can also be connected to memory 2250 that is configured to store data and/or instructions to facilitate the operation of the wireless device, and/or to provide storage of information for the user.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 5 GHz, such as in a range from about 500 MHz to 3 GHz.

Further examples of the electronic devices that aspects of this disclosure may be implemented include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc.

Having described above several aspects of at least one embodiment, it is to be appreciated various alterations, modifications, and improvements will readily occur to those skilled in the art. Such alterations, modifications, and improvements are intended to be part of this disclosure and are intended to be within the scope of the disclosure. Accordingly, the foregoing description and drawings are by way of example only, and the scope of the disclosure should be determined from proper construction of the appended claims, and their equivalents.

1. An acoustic wave device, comprising:
a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material;
a pair of interdigital transducer electrodes disposed on an upper surface of the layer of piezoelectric material, each interdigital transducer electrode including a bus bar, and a plurality of electrode fingers extending from the bus bar to distal ends of the plurality of electrode fingers at an edge region of the interdigital transducer electrode; and
trench portions located in the upper surface of the layer of piezoelectric material, said trench portions being overlapped by the edge regions of the interdigital transducer electrodes, the plurality of electrode fingers having a width at their distal end that is greater than the width of the rest of the electrode finger.

2. The acoustic wave device of claim 1 wherein the trench portions each have a depth relative to the upper surface of the layer of piezoelectric material of between about 0.004λ and 0.02λ, where λ is a wavelength of an acoustic wave generated by the pair of interdigital transducer electrodes during operation.

3. The acoustic wave device of claim 1 wherein the trench portions are located in the areas of the upper surface of the layer of piezoelectric material that are overlapped by the edge regions of the interdigital transducer electrodes and are not covered by the material of the interdigital transducer electrodes.

4. The acoustic wave device of claim 1 wherein the trench portions extend discontinuously in a direction of propagation of an acoustic wave to be generated by the pair of interdigital transducer electrodes.

5. The acoustic wave device of claim 1 wherein the trench portions each have a length of between about 0.5λ and 1λ, where λ is a wavelength of the acoustic wave to be generated.

6. The acoustic wave device of claim 1 wherein the bus bars of the pair of interdigital transducer electrodes are opposing and the plurality of electrode fingers of each interdigital transducer electrode extend towards the bus bar of the other electrode.

7. The acoustic wave device of claim 1 wherein the plurality of electrode fingers of each interdigital transducer electrode interleave with one another in an active region of the pair of interdigital transducer electrodes, and form gap regions between the ends of the plurality of fingers of one of the electrodes and the bus bar of the other electrode.

8. The acoustic wave device of claim 7 wherein the edge regions of the pair of interdigital transducer electrodes are located within the active region and on opposing sides of the active region.

9. The acoustic wave device of claim 8 wherein the active region includes a central region and the edge regions of the interdigital transducer electrodes, each edge region extending from tips of the plurality of electrode fingers of one of the interdigital transducer electrodes towards a center of the central region.

10. The acoustic wave device of claim 9 wherein a duty factor of the pair of interdigital transducer electrodes in the edge regions of the interdigital transducer electrodes is larger than a duty factor of the pair of interdigital transducer electrodes in the central region of the active region.

11. The acoustic wave device of claim 1 wherein a duty factor at the distal end of the plurality of electrode fingers is between about 0.5 and 0.64.

12. The acoustic wave device of claim 1 wherein the portion of the interdigital transducer electrode with greater width is contiguous with one or more adjacent trench portions in the layer of piezoelectric material and has the same length as the length of the one or more trench portions.

13. The acoustic wave device of claim 1 wherein the bus bars of the pair of interdigital transducer electrodes are opposing and the plurality of electrode fingers of each interdigital transducer electrode extend towards the bus bar of the other electrode.

14. The acoustic wave device of claim 7 wherein the trench portions in the upper surface of the layer of piezoelectric material are also overlapped with at least part of the gap regions.

15. The acoustic wave device of claim 14 wherein the trench portions each have a length in a direction perpendicular to the direction of propagation of an acoustic wave to be generated by the pair of interdigital transducer electrodes that extends from the respective edge region to the bus bar of the other electrode.

16. The acoustic wave device of claim 14 wherein each of the interdigital transducer electrodes includes a second bus bar that is located within the gap region.

17. The acoustic wave device of claim 16 wherein the trench portions each have a length that extends from the respective edge region to the second bus bar of the other electrode.

18. A radio frequency filter comprising at least one acoustic wave device, the at least one acoustic wave device including:
a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material;
a pair of interdigital transducer electrodes disposed on an upper surface of the layer of piezoelectric material, each interdigital transducer electrode including a bus bar, and a plurality of electrode fingers extending from the bus bar to distal ends of the plurality of electrode fingers at an edge region of the interdigital transducer electrode; and
trench portions located in the upper surface of the layer of piezoelectric material, said trench portions being overlapped by the edge regions of the interdigital transducer electrodes, the plurality of electrode fingers having a width at their distal end that is greater than the width of the rest of the electrode finger.

19. The radio frequency filter of claim 18 wherein the at least one acoustic wave device includes a first acoustic wave device and a second acoustic wave device, the plurality of electrode fingers of the first acoustic wave device having a different duty cycle at their distal ends than the plurality of electrode fingers of the second acoustic wave device.

20. The radio frequency filter of claim 19 wherein the trench portions of the first acoustic wave device have a same trench depth as the trench portions of the second acoustic wave device.

21. An electronics module comprising at least one radio frequency filter that includes at least one acoustic wave device, the at least one acoustic wave device including:
a layer of carrier substrate; a layer of dielectric material, the layer of dielectric material having a lower surface disposed against an upper surface of the layer of carrier substrate; a layer of piezoelectric material, the layer of piezoelectric material having a lower surface disposed against an upper surface of the layer of dielectric material;
a pair of interdigital transducer electrodes disposed on an upper surface of the layer of piezoelectric material, each interdigital transducer electrode including a bus bar, and a plurality of electrode fingers extending from the bus bar to distal ends of the plurality of electrode fingers at an edge region of the interdigital transducer electrode; and
trench portions located in the upper surface of the layer of piezoelectric material, said trench portions being overlapped by the edge regions of the interdigital transducer electrodes, and the plurality of electrode fingers having a width at their distal end that is greater than the width of the rest of the electrode finger.
